(19) United States
(12) Patent Application Publication
(10) Pub. No.: US 2026/0047488 A1
(43) Pub. Date: Feb. 12, 2026

(54) SEMICONDUCTOR PACKAGE AND METHOD FOR MANUFACTURING THE SAME

(71) Applicant: Samsung Electronics Co., Ltd., Suwon-si (KR)

(72) Inventor: HYUNSOO CHUNG, Suwon-si (KR)

(21) Appl. No.: 19/059,643

(22) Filed: Feb. 21, 2025

(30) Foreign Application Priority Data
Aug. 9, 2024 (KR) 10-2024-0107024

(51) Int. Cl. H01L 25/18; H01L 23/00; H01L 23/538; H10B 80/00; H10D 80/30; H10D 88/00

(52) U.S. Cl. CPC H01L 25/18; H01L 23/5384; H01L 24/08; H01L 24/16; H10B 80/00; H10D 80/30; H10D 88/00; H01L 24/32; H01L 24/73; H01L 24/94; H01L 2224/08148; H01L 2224/08235; H01L 2224/16148; H01L 2224/32145; H01L 2224/73204; H01L 2224/94; H01L 2924/1431; H01L 2924/1436; H01L 2924/19011; H01L 2924/19041

(57) ABSTRACT

A semiconductor package including a redistribution structure, a first capacitor die on the redistribution structure, a 3D integrated circuit structure on the redistribution structure, and next to the first capacitor die, a logic die on the first capacitor die, and on the 3D integrated circuit structure;, and a memory stack on the 3D integrated circuit structure. The 3D integrated circuit structure including a second capacitor die and a buffer die on the second capacitor die.

### CROSS-REFERENCE TO RELATED APPLICATION

This application claims priority under 35 U.S.C. 119 to and the benefit of Korean Patent Application No. 10-2024-0107024 filed in the Korean Intellectual Property Office on Aug. 9, 2024, the entire contents of which are incorporated herein by reference.

### BACKGROUND OF THE INVENTION

### (a) Field of the Invention

The present disclosure relates to a semiconductor package and a method for manufacturing the same.

### (b) Description of the Related Art

A semiconductor package including a logic die and a high bandwidth memory (HBM) spaced apart from each other in a horizontal direction can include a bridge die, forming a signal routing path between the logic die and the high bandwidth memory (HBM), below the logic die and the high bandwidth memory (HBM). Further, with the development of artificial intelligence (AI) and high performance computing (HPC) technologies, a power integrity (PI) becomes more important in the semiconductor package including the logic die and the high bandwidth memory (HBM), and in order to enhance the power integrity (PI) of the semiconductor package, a bridge die including a capacitor having a high-capacity capacitance is developed and used.

However, although the bridge die is used, a signal transfer distance between the logic die and the high bandwidth memory (HBM) spaced apart from each other in a horizontal direction is still long, and the long signal transfer distance between the logic die and the high bandwidth memory (HBM) can cause a problem which deteriorates a signal transmission speed between the logic die and the high bandwidth memory (HBM). Further, the bridge die, which includes the capacitor forms the capacitor in the bridge die. The bridge, which includes the capacitor, is disposed in a substrate of the semiconductor package through an embedding process. However, a scheme of forming the capacitor in the bridge die, and embedding the bridge die in which the capacitor is formed in the semiconductor package is complex and difficult in a manufacturing process. As a result, a problem may exist in which productivity and reliability for the semiconductor package are reduced.

### SUMMARY OF THE INVENTION

A logic die and a high bandwidth memory (HBM) may be directly connected without a bridge die.

A capacitor die may be disposed below each of the logic die and the high bandwidth memory (HBM).

An embodiment of the present disclosure provides a semiconductor package which may include: a redistribution structure; a first capacitor die on the redistribution structure; a 3D integrated circuit structure on the redistribution structure, and next to the first capacitor die; a logic die on the first capacitor die, and on the 3D integrated circuit structure; and a memory stack on the 3D integrated circuit structure, in which the 3D integrated circuit structure may include a second capacitor die; and a buffer die on the second capacitor die.

Another embodiment of the present disclosure provides a semiconductor package which may include: a redistribution structure; a 3D integrated circuit structure on the redistribution structure, wherein the 3D integrated circuit structure includes a first capacitor die, and a logic die on the first capacitor die; a second capacitor die on the redistribution structure, and next to the 3D integrated circuit structure; a buffer die on the 3D integrated circuit structure, and on the second capacitor die; and a memory stack on the buffer die.

Another embodiment of the present disclosure provides a semiconductor package which may include: a redistribution structure; one or more first capacitor dies on the redistribution structure; a plurality of 3D integrated circuit structures on the redistribution structure, and around the one or more first capacitor dies; a logic die on the one or more first capacitor dies, and on the plurality of 3D integrated circuit structures; a plurality of memory stacks around the logic die, wherein each of the plurality of memory stacks is disposed on a corresponding 3D integrated circuit structure among the plurality of 3D integrated circuit structures; and a molding material covering the one or more first capacitor dies, the plurality of 3D integrated circuit structures, the logic die, and the plurality of memory stacks on the redistribution structure, in which each of the plurality of 3D integrated circuit structures may include a second capacitor die, and a buffer die on the second capacitor die.

An activation surface of a buffer die of a high bandwidth memory (HBM), and an activation surface of a logic die are directly connected to reduce a signal transfer distance between the high bandwidth memory (HBM) and the logic die, and enhance a signal transfer speed.

A capacitor die is disposed below each of the high bandwidth memory (HBM) and the logic die to enhance power integrity (PI) of a semiconductor package.

### BRIEF DESCRIPTION OF THE DRAWINGS

FIG. 1 is a cross-sectional view illustrating a semiconductor package according to an embodiment.

FIG. 2 is an enlarged cross-sectional view of region A of FIG. 1.

FIG. 3 is a cross-sectional view illustrating a semiconductor package according to an embodiment.

FIG. 4 is a plan view illustrating an upper surface of the semiconductor package of FIG. 1 or an upper surface of the semiconductor package of FIG. 3.

FIG. 5 is a cross-sectional view illustrating a semiconductor package according to an embodiment.

FIG. 6 is a cross-sectional view illustrating a semiconductor package according to an embodiment.

FIG. 7 is a plan view illustrating an upper surface of the semiconductor package of FIG. 5 or an upper surface of the semiconductor package of FIG. 6.

FIGS. 8 to 11 are cross-sectional views illustrated to describe a method for manufacturing a 3D integrated circuit structure (SA) of FIG. 1.

FIGS. 12 to 22 are cross-sectional views illustrated to describe a method for manufacturing the semiconductor package according to an embodiment in FIG. 1.

### DETAILED DESCRIPTION OF THE EMBODIMENTS

Hereinafter, an embodiment of the present disclosure will be described more fully hereinafter with reference to the accompanying drawings so as to be easily implemented by those skilled in the art to which the present disclosure pertains. The present disclosure may be implemented in various different forms and is not limited to embodiments described herein.

Parts not associated with required description are omitted for clearly describing the present invention and like reference numerals designate like elements throughout the specification. Throughout the specification, when a component is described as “including” or “include” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

In addition, each configuration illustrated in the drawings is arbitrarily shown for understanding and ease of description, but the present disclosure is not limited thereto.

Throughout this specification, when it is described that a part is “connected” with another part, it means that the certain part may be “directly connected” with another part and the elements “indirectly connected” to each other with a third member interposed therebetween as well. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, to be referred to as “on” or “on” a reference portion is located above or below the reference portion, and does not particularly mean to “above” or “on” the direction opposite to gravity.

Further, throughout the specification, “plan view” means that a target part is viewed from the top, and “cross-sectional view” means that a cross section vertically cutting the target part is viewed from the side.

Hereinafter, semiconductor packages 100AA, 100AB, 100BA, and 100BB, and a method for manufacturing the semiconductor package 100AA according to an embodiment will be described with reference to drawings.

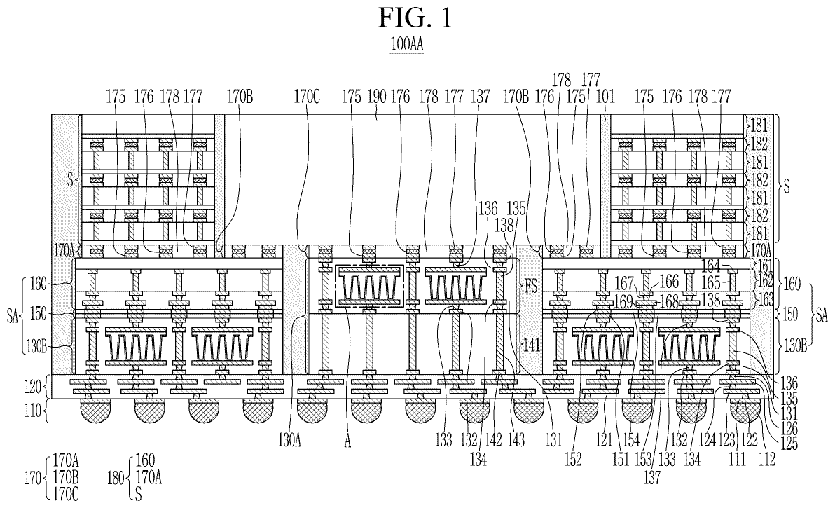

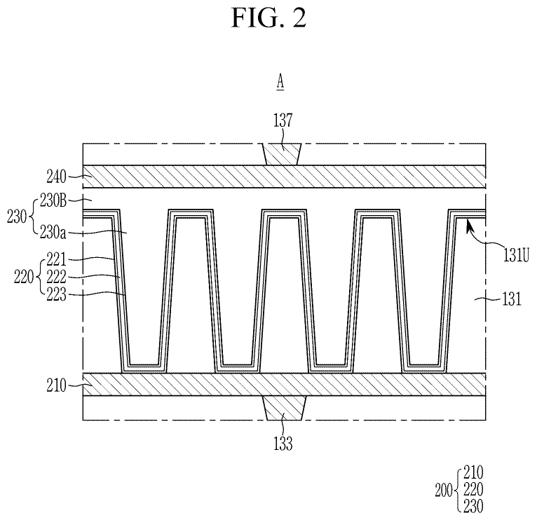

FIG. 1 is a cross-sectional view illustrating a semiconductor package 100AA according to an embodiment. FIG. 2 is an enlarged cross-sectional view of region A of the semiconductor package 100AA in FIG. 1.

Referring to FIG. 1, the semiconductor package 100AA may include a connection structure 110, a redistribution structure 120, a first capacitor die 130A, a 3D integrated circuit structure SA, an upper interconnection structure 170, a logic die 190, a memory stack S, and a molding material 101. In an embodiment, the semiconductor package 100AA may include a system in package (SIP). The semiconductor package 100AA in which two or more semiconductor dies are implemented as one semiconductor package may operate like one chip. In an embodiment, the semiconductor package 100AA may be manufactured based on a fan out wafer level package (FOWLP) or fan out panel level package (FOPLP) technology.

The connection structure 110 may be disposed on a lower surface of the redistribution structure 120. The connection structure 110 may include connection pads 111 and external connection members 112. Each of connection pads 111 may be disposed between each of external connection members 112 and each of first redistribution vias 122 of the redistribution structure 120. Each of connection pads 111 may electrically connect each of first redistribution vias 122 of the redistribution structure 120 to each of external connection members 112. Each of external connection members 112 may be disposed below each of connection pads 111. The external connection members 112 may electrically connect the semiconductor package 100AA to an external device.

The redistribution structure 120 may be disposed on the connection structure 110. The redistribution structure 120 may include a dielectric 121, and the first redistribution vias 122, first redistribution lines 123, second redistribution vias 124, second redistribution lines 125, and third redistribution vias 126 in the dielectric 121. In another embodiment, the redistribution structure 120 including less or more redistribution lines and redistribution vias may be included in the scope of the present disclosure.

The dielectric 121 protects and insulates the first redistribution vias 122, the first redistribution lines 123, the second redistribution vias 124, the second redistribution lines 125, and the third redistribution vias 126. The first capacitor die 130A, the 3D integrated circuit structure SA, and the molding material 101 may be disposed on an upper surface of the dielectric 121. The connection structure 110 may be disposed on a lower surface of the dielectric 121.

The first redistribution vias 122, the first redistribution lines 123, the second redistribution vias 124, the second redistribution lines 125, and the third redistribution vias 126 may be disposed sequentially from the bottom, and may constitute a vertical power or signal routing path which electrically connects the first capacitor die 130A to the connection structure 110, and the 3D integrated circuit structure SA to the connection structure 110. Each of the first redistribution vias 122, the second redistribution vias 124, and the third redistribution vias 126 may have a shape in which a width decreases from the bottom to the top.

The first capacitor die 130A may be disposed on the redistribution structure 120. The first capacitor die 130A may be in contact with the redistribution structure 120. The first capacitor die 130A may be disposed below the logic die (a first logic die 190). The first capacitor die 130A may be disposed next to the 3D integrated circuit structure SA. There may be a plurality of first capacitor dies 130A. A level of an upper surface of the first capacitor die 130A may be the same as a level of an upper surface of the 3D integrated circuit structure SA (e.g., the upper surface of the first capacitor die 130A may be coplanar with the upper surface of the 3D integrated circuit structure SA). In an embodiment, the first capacitor die 130A may include an integrated stack capacitor (ISC) die. In an embodiment, the first capacitor die 130A may serve as a decoupling capacitor. The first capacitor die 130A may protect the logic die 190 from noise in a process in which power is transferred to the logic die 190. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact”another element, there are no intervening elements present at the point of contact.

The first capacitor die 130A may include a front side structure FS and a capacitor die base 141. The front side structure FS may be located on the capacitor die base 141. The front side structure FS may include capacitor structures 200, an inter metal dielectric (IMD) 131, and lower connection pads 132, first contact plugs 133, first wiring lines 134, second contact plugs 135, second wiring lines 136, third contact plugs 137, and upper connection pads 138 in the inter metal dielectric (IMD) 131.

The lower connection pads 132, the first contact plugs 133, the first wiring lines 134, the second contact plugs 135, the second wiring lines 136, the third contact plugs 137, and the upper connection pads 138 may be disposed sequentially from the bottom, and may constitute a vertical power or signal routing path which electrically connects the logic die 190 to the capacitor die base 141. The lower connection pads 132, the first contact plugs 133, the capacitor structure 200, the third contact plugs 137, and the upper connection pads 138 may be disposed sequentially from the bottom, and may constitute a vertical power routing path which electrically connects the logic die 190 to the capacitor die base 141.

The first wiring lines 134 and the second wiring lines 136 are formed in a horizontal direction to transfer a signal and power between layers at the same level. The first contact plugs 133 and the second contact plugs 135 are formed in a vertical direction to transfer the signal and the power between layers at different levels. In an embodiment, the inter metal dielectric (IMD) 131 may include SiO_{2,} SiOC, SiOH, SiOCH, or a low-k dielectric layer. In an embodiment, each of the lower connection pads 132, the first contact plugs 133, the first wiring lines 134, the second contact plugs 135, the second wiring lines 136, the third contact plugs 137, and the upper connection pads 138 may include at least one of copper, aluminum, tungsten, nickel, gold, tin, titanium, and an alloy thereof. In another embodiment, the front side structure FS including less or more lower connection pads, first contact plugs, first wiring lines, second contact plugs, second wiring lines, third contact plugs, and upper connection pads may be included in the scope of the present disclosure.

Referring to FIG. 2, the capacitor structure 200 may be disposed between the first contact plug 133 and the third contact plug 137 in the inter metal dielectric (IMD) 131. The capacitor structure 200 may include a lower plate layer 210, a capacitor 220, a conductive interconnection member 230, and an upper plate layer 240. In an embodiment, the capacitor structure 200 may include an integrated stack capacitor (ISC) structure.

The lower plate layer 210 may be disposed below a lower surface of a lower electrode 221 of the capacitor 220 and a lower surface of the inter metal dielectric (IMD) 131, and may electrically connect the lower electrode 221 of the capacitor 220 to the first contact plug 133. In an embodiment, the lower plate layer 210 may include TiN.

The capacitor 220 may be disposed between the lower plate layer 210 and the conductive interconnection member 230, and disposed in the inter metal dielectric (IMD) 131. The capacitor 220 may include a lower electrode 221, a dielectric film 222, and an upper electrode 223. The capacitor 220 may be extended in the vertical direction within tens of thousands or more through-holes formed within the inter metal dielectric (IMD) 131, and consecutively (e.g., continuously) extended in the horizontal direction on the inter metal dielectric (IMD) 131 around the through-holes. As such, the capacitor 220 has horizontal and vertical 3D capacitor structures, and has a high-capacity capacitance. In a plan view, tens of thousands or more through-holes formed within the inter metal dielectric (IMD) 131 may include a circular, elliptical, or polygonal shape.

The lower electrode 221 may be extended consecutively and conformally along insides of the through-holes formed in the inter metal dielectric (IMD) 131 (an upper surface of the lower plate layer 210 and an inner surface of the through-hole), and along a surface 131U of the inter metal dielectric (IMD) 131 around the through-holes. The lower electrode 221 may be in contact with the lower plate layer 210, and may be electrically connected to the lower plate layer 210. In an embodiment, the lower electrode 221 may include a vertical cylindrical shape or conical shape. In an embodiment, the lower electrode 221 may include a metal nitride film, a metal oxide film, a metal oxynitride film, or a combination thereof. In an embodiment, the lower electrode 221 may include TiN, CoN, NbN, SnO₂, or a combination thereof.

The dielectric film 222 may be extended conformally along the lower electrode 221 on the lower electrode 221. In an embodiment, the dielectric film 222 may include the vertical cylindrical shape or conical shape. In an embodiment, the dielectric film 222 may include the metal oxide film. In an embodiment, the dielectric film 222 may include AlO₂, ZrO₂, HfO₂, Nb₂O₅, CeO₂, TiO₂, or a combination thereof. In an embodiment, the dielectric film 222 may include a multilayer film in which AlO₂ and ZrO₂ are alternately stacked.

The upper electrode 223 may be extended conformally along the dielectric film 222 on the dielectric film 222. The upper electrode 223 may be in contact with the conductive interconnection member 230, and may be electrically connected to the conductive interconnection member 230. In an embodiment, the upper electrode 223 may include the vertical cylindrical shape or conical shape. In an embodiment, the upper electrode 223 may include the metal nitride film, the metal oxide film, the metal oxynitride film, or the combination thereof. In an embodiment, the upper electrode 223 may include TiN, CoN, NbN, SnO₂, or the combination thereof.

The conductive interconnection member 230 may be disposed between the capacitor 220 and the upper plate layer 240, and may be electrically connected to the capacitor 220 and the upper plate layer 240. The conductive interconnection member 230 may include a first region and a second region. The first region may include buried plugs 230A which are formed in the through-holes on the capacitor 220. The second region may include a plate member 230B which is disposed on the buried plugs 230A, and on portions of the capacitor 220 extended in the horizontal direction along the surface 131U of the inter metal dielectric (IMD) 131 around the through-holes, and electrically connects the buried plugs 230A to the upper plate layer 240. The buried plugs 230A and the plate member 230B of the conductive interconnection member 230 may be made of one material, and integrally formed. In an embodiment, the conductive interconnection member 230 may include aluminum.

The upper plate layer 240 may be disposed on the conductive interconnection member 230, and may electrically connect the third contact plug 137 to the conductive interconnection member 230. In an embodiment, the upper plate layer 240 may include TiN.

The capacitor structure 200 according to the present disclosure may suppress power noise in a high-frequency band of hundreds of MHz, and has a large capacitance density. As such, the capacitor structure 200 is disposed on a path in which power is routed to the logic die 190 to enhance the power integrity (PI) of the logic die 190.

Referring back to FIG. 1, the capacitor die base 141 may be disposed below the front side structure FS. The capacitor die base 141 may be a die formed from a wafer. In an embodiment, the capacitor die base 141 may include silicon or another semiconductor material. The capacitor die base 141 may include connection pads 142 and through silicon vias 143. A vertical height of the capacitor die base 141 may be equal to a sum of a height of a lower interconnection structure 150 of the 3D integrated circuit structure SA and a height of a buffer die 160.

Each of connection pads 142 may be disposed between each of third redistribution vias 126 of the redistribution structure 120 and each of through silicon vias 143. Each of connection pads 142 may electrically connect each of through silicon vias 143 to each of third redistribution vias 126 of the redistribution structure 120. In an embodiment, the connection pads 142 may include at least one of copper, aluminum, tungsten, nickel, gold, tin, titanium, and alloy thereof.

Each of through silicon vias 143 may be disposed between each of connection pads 142 and each of lower connection pads 132 of the front side structure FS. Each of through silicon vias 143 may electrically connect each of lower connection pads 132 of the front side structure FS to each of connection pads 142. In an embodiment, the through silicon vias 143 may include at least one of tungsten, aluminum, copper, and an alloy thereof. In another embodiment, the capacitor die base 141 including less or more connection pads and through silicon vias may be included in the scope of the present disclosure.

The 3D integrated circuit structure SA may be disposed on the redistribution structure 120. The 3D integrated circuit structure SA may be in contact with the redistribution structure 120. The 3D integrated circuit structure SA may be disposed below the memory stack S, and below the logic die 190. The 3D integrated circuit structure SA may be disposed next to (e.g., adjacent in a horizontal direction) the first capacitor die 130A. There may be a plurality of 3D integrated circuit structures SA. The plurality of 3D integrated circuit structures SA may be disposed around the first capacitor die 130A. The level of the upper surface of the first capacitor die 130A may be the same as the level (e.g., in a vertical direction) of the upper surface of the 3D integrated circuit structure SA (e.g., the upper surface of the first capacitor die 130A may be coplanar with the upper surface of the 3D integrated circuit structure SA).

The 3D integrated circuit structure SA may include a second capacitor die 130B, the lower interconnection structure 150, and the buffer die (a base die; a second logic die) 160.

The second capacitor die 130B may be disposed at a lowermost portion of the 3D integrated circuit structure SA. The second capacitor die 130B may include the same configuration as the front side structure FS of the first capacitor die 130A. In an embodiment, the second capacitor die 130B may include an integrated stack capacitor (ISC) die. In an embodiment, the second capacitor die 130B may protect the high bandwidth memory 180 from noise in a process in which power is transferred to the high bandwidth memory 180.

The lower interconnection structure 150 may be disposed between the second capacitor die 130B and the buffer die 160, and may electrically connect the second capacitor die 130B to the buffer die 160. The lower interconnection structure 150 may bond the second capacitor die 130B and the buffer die 160 by hybrid bonding (hybrid copper bonding). The hybrid bonding bonds semiconductor dies by a method of fusing the same materials of the semiconductor dies by using a binding property of the same material. Here, hybrid means bonding two different types, for example, bonding the semiconductor dies by first type metal-meal bonding and second type non-metal-non-metal bonding. By the hybrid bonding, input/output terminals having ultra-fine pitches may be formed.

The lower interconnection structure 150 may include first conductive pads 151, second conductive pads 152, first silicon insulation layers 153, and second silicon insulation layer 154. The first conductive pads 151 may be disposed on an upper surface of the second capacitor die 130B. The first conductive pads 151 may penetrate the first silicon insulation layer 153. The second conductive pads 152 may be disposed on a lower surface of the buffer die 160, and on the first conductive pads 151. The second conductive pads 152 may penetrate the second silicon insulation layer 154. The first silicon insulation layer 153 may be disposed on the upper surface of the second capacitor die 130B. The first silicon insulation layer 153 may surround and insulate the first conductive pads 151. The second silicon insulation layer 154 may be disposed on the lower surface of the buffer die 160, and on the first silicon insulation layer 153. The second silicon insulation layer 154 may surround and insulate the second conductive pads 152.

Each of first conductive pads 151 may be directly bonded to each of second conductive pads 152 by metal-metal hybrid bonding. Metal bonding is made on an interface between the first conductive pad 151 and the second conductive pad 152 by the metal-metal hybrid bonding. In an embodiment, each of the first conductive pad 151 and the second conductive pad 152 may include copper or a metallic material to which hybrid bonding may be applied. The first conductive pad 151 and the second conductive pad 152 are made of the same material, and after the hybrid bonding, the interface between the first conductive pad 151 and the second conductive pad 152 may be removed. The second capacitor die 130B and the buffer die 160 may be electrically connected to each other through the first conductive pad 151 and the second conductive pad 152.

The first silicon insulation layer 153 may be directly bonded to the second silicon insulation layer 154 by non-metal-non-metal hybrid bonding. Covalent bonding is made on the interface between the first silicon insulation layer 153 and the second silicon insulation layer 154 by the non-metal-non-metal hybrid bonding. In an embodiment, each of the first silicon insulation layer 153 and the second silicon insulation layer 154 may include silicon oxide, TEOS forming oxide, silicon nitride, silicon oxynitride, or other appropriate dielectric materials. In an embodiment, each of the first silicon insulation layer 153 and the second silicon insulation layer 154 may include SiO2, SiN, or SiCN. The first silicon insulation layer 153 and the second silicon insulation layer 154 are made of the same material, and after the hybrid bonding, the interface between the first silicon insulation layer 153 and the second silicon insulation layer 154 may be removed.

The buffer die 160 may be disposed on the second capacitor die 130B. The buffer die 160 may be electrically connected to the second capacitor die 130B by the lower interconnection structure 150. The buffer die 160 may be disposed so that activation surface of the buffer die 160 (or an activation surface of the buffer die base 162) faces the logic die 190, and the memory stack S. When data is sent and received between devices in which processing speeds, processing units, and usage time of data are different from each other, data may be lost due to a processing speed difference, a processing unit difference, and a usage time difference of data between respective devices. In order to prevent the loss, the buffer die 160 is disposed between the memory stack S and the external device to temporarily store information when data is sent and received between the memory stack S and the external device in the buffer die 160. When data is transmitted to the memory stack S or data is received from the memory stack S, the buffer die 160 may sequentially pass data after ordering data.

The buffer die 160 may serve as the high bandwidth memory (HBM) 180 jointly with the memory stack S disposed on the buffer die 160. The high bandwidth memory (HBM) 180 is a high-performance 3D stacked dynamic random-access memory (DRAM). The high bandwidth memory (HBM) 180 has multiple memory channels through a memory stack manufactured by vertically stacking memory dies to simultaneously implement a short latency and a high bandwidth compared with a DRAM product in the related art, and reduce a total area occupied by individual DRAMs on the substrate, so the HBM 180 has an advantage of being advantageous to a high bandwidth compared to an area, and being capable of reducing power consumption.

The buffer die 160 may include a front side structure 161, a buffer die base 162, and a back side power delivery network (BSPDN) 163. The buffer die 160 may be disposed so that the BSPDN 163 faces the second capacitor die 130B.

The front side structure 161 may be located on the buffer die base 162. The front side structure 161 may include an activation layer and a wiring layer. The activation layer may be disposed an activation surface (front side) of the buffer die base 162. The activation layer may include an integrated circuit structure having integrated circuit regions. In an embodiment, the integrated circuit structure may include at least one of an active device and a passive device. In an embodiment, the integrated circuit structure may include a gate structure, a source region, and a drain region. In an embodiment, the integrated circuit structure may include at least one of a transistor, a diode, a capacitor, an inductor, and a resistor. The wiring layer may be disposed on the activation layer. The wiring layer may include signal wiring lines, power wiring lines, contact plugs, and an inter metal dielectric (IMD).

The buffer die base 162 may be disposed below the front side structure 161. The buffer die base 162 may include the activation surface and a back side which is an opposite side to the activation surface. The buffer die base 162 may be a die formed from the wafer. In an embodiment, the buffer die base 162 may include silicon or another semiconductor material. The buffer die base 162 may include through silicon vias 165 and buried power rails (BPR) 164.

The through silicon vias 165 may be disposed in the buffer die base 162. Each of through silicon vias 165 may be disposed between each of upper connection pads 166 of the BSPDN 163, and each of buried power rails (BPR) 164. Each of through silicon vias 165 may electrically connect each of buried power rails (BPR) 164 to each of upper connection pads 166 of the BSPDN 163. In an embodiment, the through silicon vias 165 may include at least one of tungsten, aluminum, copper, and an alloy thereof.

Each of buried power rails (BPR) 164 may be disposed between each of through silicon vias 165 and the activation layer of the front structure 161. The buried power rails (BPR) 164 serve to transfer power to the integrated circuit structure of the activation layer. In an embodiment, the buried power rails (BPR) 164 may include at least one of cobalt, tungsten, ruthenium, and an alloy thereof.

The BSPDN 163 may be disposed on the back side which is the opposite side to the activation surface of the buffer die base 162. The BSPDN 163 refers to a structure in which power wires formed on the wiring layer of the front side structure in the related art are formed on the back side of the buffer die base 162. The power wires are disposed on the back side of the buffer die base 162 to reduce a space occupied by the power wires in the wiring layer on the front side of the buffer die base 162, and reduce an area and resistance of the wiring layer of the front side structure 161, and as a result, signal and power characteristics of a semiconductor package may be enhanced.

The BSPDN 163 may include the upper connection pads 166, the wiring contact plugs 167, power supply lines 168, lower connection pads 169, and the inter metal dielectric (IMD). The upper connection pads 166, the wiring contact plugs 167, the power supply lines 168, and the lower connection pads 169 may be disposed sequentially from the top, and may form a vertical power routing path in which power transferred via the second capacitor die 130B and the lower interconnection structure 150 is transferred to the integrated circuit structure of the activation layer. In an embodiment, the inter metal dielectric (IMD) may include SiO₂, SiOC, SiOH, SiOCH, or a low-k dielectric layer. In an embodiment, each of the upper connection pads 166, the wiring contact plugs 167, the power supply lines 168, and the lower connection pads 169 may include at least one of copper, aluminum, tungsten, nickel, gold, tin, titanium, and the alloy thereof. In another embodiment, the BSPDN 163 including less or more connection pads, contact plugs, and power supply lines may be included in the scope of the present disclosure.

The upper interconnection structures 170 may include a first interconnection structure 170A, a second interconnection structure 170B, and a third interconnection structure 170C. There may be a plurality of first interconnection structures 170A, second interconnection structures 170B, and third interconnection structures 170C. The first interconnection structures 170A may be disposed between the 3D integrated circuit structure SA and the memory stack S. Connection members 176 of the first interconnection structure 170A may electrically connect the 3D integrated circuit structure SA to the memory stack S. The second interconnection structures 170B may be disposed between the 3D integrated circuit structure SA and the logic die 190. The connection members 176 of the second interconnection structure 170B may electrically connect the 3D integrated circuit structure SA to the logic die 190. The third interconnection structures 170C may be disposed between the first capacitor die 130A and the logic die 190. The connection members 176 of the third interconnection structure 170C may electrically connect the first capacitor die 130A to the logic die 190.

Each of upper interconnection structures 170 may include the connection members 176 and insulation members 178 around the connection members 176. In an embodiment, the connection members 176 may include micro bumps. The insulation member 178 may surround, protect, and insulate the bonding pads 175 of the 3D integrated circuit structure SA, the bonding pads 175 of the first capacitor die 130A, the connection members 176, the connection pads 177 of the memory stack S, and the connection pads 177 of the logic die 190. In an embodiment, the insulation member 178 may include a non-conductive film (NCF).

According to the present disclosure, the activation surface of the buffer die 160 of the high bandwidth memory (HBM) 180, and the activation surface of the logic die 190 may be directly connected without the bridge die by the second interconnection structure 170B. As a result, the signal transfer distance between the high bandwidth memory (HBM) 180 and the logic die 190 may be reduced, and a signal transfer speed may be enhanced.

The memory stack S may be disposed on the 3D integrated circuit structure SA. The memory stack S may be disposed side by side with the logic die 190. There may be a plurality of memory stacks S. The plurality of memory stacks S may be disposed around the logic die 190. The memory stack S may include memory dies (core dies) 181 and interconnection structures 182. The memory dies 181 may be stacked in the vertical direction, and sequentially. In an embodiment, the memory dies 181 may include DRAMs. Each of interconnection structures 182 may be disposed between neighboring memory dies 181 among the memory dies 181. Each of interconnection structures 182 may include connection members and insulation members around the connection members. In an embodiment, the connection members may include micro bumps. In an embodiment, the insulation member may include the non-conductive film (NCF).

The logic die 190 may be disposed on the 3D integrated circuit structure SA, and on the first capacitor die 130A. The logic die 190 may be disposed next to the memory stack S. The logic die 190 may be disposed side by side with the memory stack S. The logic die 190 may be disposed at the center of the plurality of memory stacks S. The logic die 190 may include a logic die base including an activation surface and a back side which is the opposite side to the activation surface, and an activation layer and a front side power delivery network (FSPDN) on the activation surface. The logic die 190 may be disposed so that the activation surface of the logic die 190 (or an activation surface of a logic die base) faces the first capacitor die 130A and the 3D integrated circuit structure SA. The logic die 190 may be disposed so that the FSPDN faces the first capacitor die 130A and the 3D integrated circuit structure SA. In an embodiment, the logic die 190 may include a system on chip (SoC). In an embodiment, the logic die 190 may include an application processor AP. In an embodiment, the logic die 190 may include at least one of a central processing unit (CPU), a graphic processing unit (GPU), a signal processor, a network processor, and a codec.

The molding material 101 may cover the first capacitor die 130A, the 3D integrated circuit structure SA, the upper interconnection structure 170, the memory stack S, and the logic die 190 on the redistribution structure 120. The molding material 101 may protect the first capacitor die 130A, the 3D integrated circuit structure SA, the upper interconnection structure 170, the memory stack S, and the logic die 190 from an external environment. The upper surface of the memory stack S and the upper surface of the logic die 190 may be exposed to the outside from the molding material 101. For example, the upper surface of the memory stack S and the upper surface of the logic die 190 may not be covered by the molding material 101. The upper surface of the memory stack S, the upper surface of the logic die 190, and the upper surface of the molding material 101 may be coplanar.

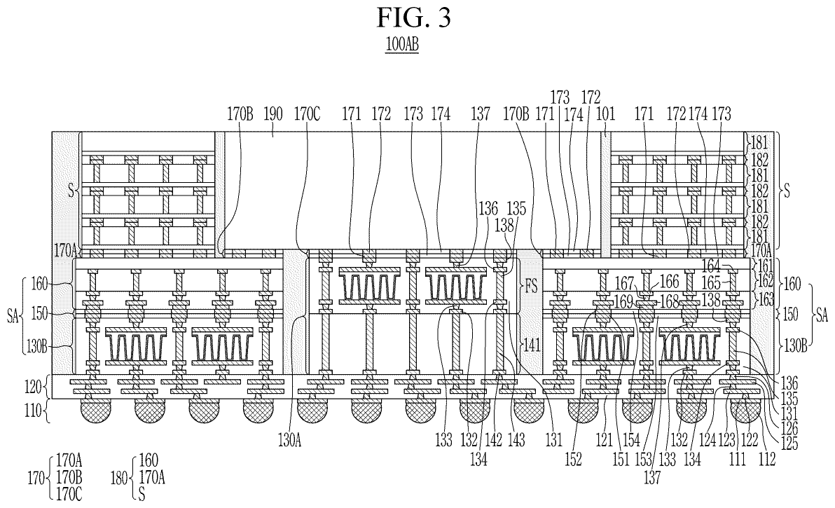

FIG. 3 is a cross-sectional view illustrating a semiconductor package 100AB according to an embodiment.

Referring to FIG. 3, the semiconductor package 100AB may be formed in a scheme in which the first capacitor die 130A and the 3D integrated circuit structure SA at a lower portion, and the memory stack S and the logic die 190 at an upper portion are bonded by hybrid bonding.

The upper interconnection structures 170 may include a first interconnection structure 170A, a second interconnection structure 170B, and a third interconnection structure 170C. The first interconnection structures 170A may be disposed between the 3D integrated circuit structure SA and the memory stack S. The first interconnection structures 170A may electrically connect the 3D integrated circuit structure SA to the memory stack S. The second interconnection structures 170B may be disposed between the 3D integrated circuit structure SA and the logic die 190. The second interconnection structures 170B may electrically connect the 3D integrated circuit structure SA to the logic die 190. The third interconnection structures 170C may be disposed between the first capacitor die 130A and the logic die 190. The third interconnection structure 170C may electrically connect the first capacitor die 130A to the logic die 190.

The upper interconnection structures 170 may include first conductive pads 171, second conductive pads 172, a first silicon insulation layer 173, and a second silicon insulation layer 174. The first conductive pads 171 may be disposed on the upper surface of the first capacitor die 130A, and on the upper surface of the 3D integrated circuit structure SA. The first conductive pads 171 may penetrate the first silicon insulation layer 173. The second conductive pads 172 may be disposed on the lower surface of the memory stack S, on the lower surface of the logic die 190, and on the first conductive pads 171. The second conductive pads 172 may penetrate the second silicon insulation layer 174. The first silicon insulation layer 173 may be disposed on the upper surface of the first capacitor die 130A, and on the upper surface of the 3D integrated circuit structure SA. The first silicon insulation layer 173 may surround and insulate the first conductive pads 171. The second silicon insulation layer 174 may be disposed on the lower surface of the memory stack S, on the lower surface of the logic die 190, and on the first silicon insulation layer 173. The second silicon insulation layer 174 may surround and insulate the second conductive pads 172.

Each of first conductive pads 171 may be directly bonded to each of second conductive pads 172 by metal-metal hybrid bonding. Metal bonding is made on an interface between the first conductive pad 171 and the second conductive pad 172 by the metal-metal hybrid bonding. In an embodiment, each of the first conductive pad 171 and the second conductive pad 172 may include copper or a metallic material to which hybrid bonding may be applied. The first conductive pad 171 and the second conductive pad 172 are made of the same material, and after the hybrid bonding, the interface between the first conductive pad 171 and the second conductive pad 172 may be removed. The first capacitor die 130A and the logic die 190, the 3D integrated circuit structure SA and the memory stack S, and the 3D integrated circuit structure SA and the logic die 190 may be electrically connected to each other through the first conductive pad 171 and the second conductive pad 172.

The first silicon insulation layer 173 may be directly bonded to the second silicon insulation layer 174 by non-metal-non-metal hybrid bonding. Covalent bonding is made on the interface between the first silicon insulation layer 173 and the second silicon insulation layer 174 by the non-metal-non-metal hybrid bonding. In an embodiment, each of the first silicon insulation layer 173 and the second silicon insulation layer 174 may include silicon oxide, TEOS forming oxide, silicon nitride, silicon oxynitride, or other appropriate dielectric materials. In an embodiment, each of the first silicon insulation layer 173 and the second silicon insulation layer 174 may include SiO2, SiN, or SiCN. The first silicon insulation layer 173 and the second silicon insulation layer 174 are made of the same material, and after the hybrid bonding, the interface between the first silicon insulation layer 173 and the second silicon insulation layer 174 may be removed.

According to the present disclosure, the activation surface of the buffer die 160 of the high bandwidth memory (HBM) 180, and the activation surface of the logic die 190 may be directly connected without a bridge die by the second interconnection structure 170B formed by the hybrid bonding. As a result, the signal transfer distance between the high bandwidth memory (HBM) 180 and the logic die 190 may be reduced, and a signal transfer speed may be enhanced.

The components described regarding FIG. 1 may be applied to components other than the components described regarding FIG. 3.

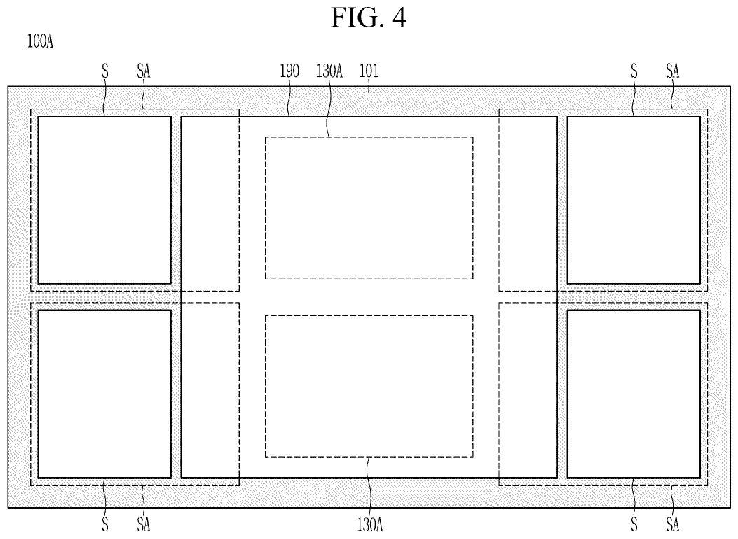

FIG. 4 is a plan view illustrating an upper surface of the semiconductor package 100AA of FIG. 1 or an upper surface of the semiconductor package 100AB of FIG. 3. The memory stacks S and the logic die 190 are illustrated in solid lines, and the first capacitor die 130A and the 3D integrated circuit structures SA are illustrated in dotted lines.

Referring to FIG. 4, the memory stacks S may be disposed around the logic die 190. One or more first capacitor dies 130A may be disposed below the logic die 190. Each of 3D integrated circuit structures SA may be disposed below each of memory stacks S, and below the logic die 190.

A footprint of the first capacitor die 130A may be included in a footprint of the logic die 190. The footprints of each of memory stacks S may be included in the footprints of each 3D integrated circuit structures SA. The footprints of each of 3D integrated circuit structures SA may overlap with the footprint of the logic die 190 and the footprints of each of memory stacks S.

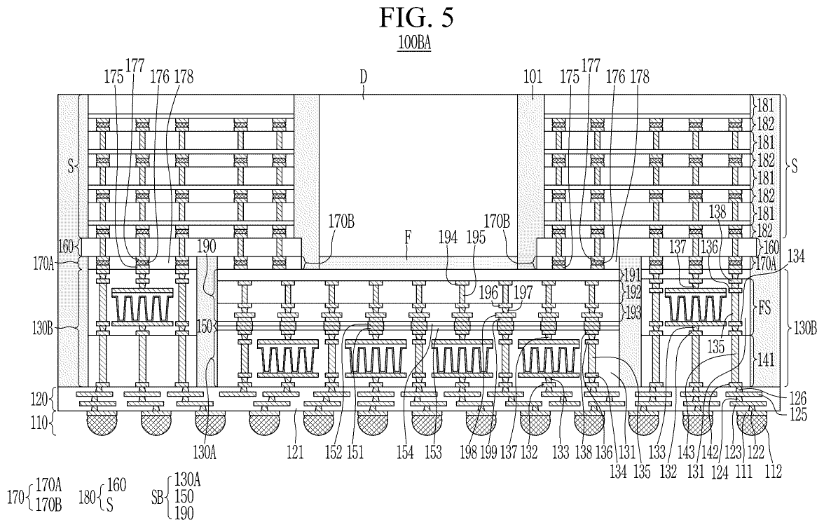

FIG. 5 is a cross-sectional view illustrating a semiconductor package 100BA according to an embodiment.

Referring to FIG. 5, the semiconductor package 100BA may include a connection structure 110, a redistribution structure 120, a 3D integrated circuit structure SB, a second capacitor die 130B, an upper interconnection structure 170, a high bandwidth memory 180, and a molding material 101. In an embodiment, the semiconductor package 100BA may include a system in package (SIP). The semiconductor package 100BA in which two or more semiconductor dies are implemented as one semiconductor package may operate like one chip. In an embodiment, the semiconductor package 100BA may be manufactured based on a fan out wafer level package (FOWLP) or fan out panel level package (FOPLP) technology.

The 3D integrated circuit structure SB may be disposed on the redistribution structure 120. The 3D integrated circuit structure SB may be in contact with the redistribution structure 120. The 3D integrated circuit structure SB may be disposed below a dummy die D, and below the high bandwidth memory (HBM) 180. The 3D integrated circuit structure SB may be disposed next to the second capacitor die 130B. A level of an upper surface of the 3D integrated circuit structure SB may be the same as a level of an upper surface of the second capacitor die 130B (e.g., the upper surface of the 3D integrated circuit structure SB may be coplanar with the upper surface of the second capacitor die 130B). The 3D integrated circuit structure SB may include the first capacitor die 130A, the lower interconnection structure 150, and the logic die (the first logic die) 190.

The first capacitor die 130A may be disposed at a lowermost portion of the 3D integrated circuit structure SB. The first capacitor die 130A may include the same configuration as the front side structure FS of the first capacitor die 130A of FIG. 1. In an embodiment, the first capacitor die 130A may protect the logic die 190 from noise in the process in which power is transferred to the logic die 190.

The lower interconnection structure 150 may be disposed on the first capacitor die 130A. The lower interconnection structure 150 may include the same configuration as the lower interconnection structure 150 of FIG. 1.

The logic die 190 may be disposed on the lower interconnection structure 150. The logic die 190 may include a front side structure 191, a logic die base192, and a BSPDN 193. The logic die 190 may be disposed so that the BSPDN 193 faces the first capacitor die 130A.

The front side structure 191 may be located on the logic die base 192. The front side structure 191 may include an activation layer and a wiring layer. The activation layer may be disposed on a front side of the logic die base 192. The activation layer may include an integrated circuit structure having integrated circuit regions. In an embodiment, the integrated circuit structure may include at least one of an active device and a passive device. In an embodiment, the integrated circuit structure may include a gate structure, a source region, and a drain region. In an embodiment, the integrated circuit structure may include at least one of a transistor, a diode, a capacitor, an inductor, and a resistor. The wiring layer may be disposed on the activation layer. The wiring layer may include signal wiring lines, power wiring lines, contact plugs, and an inter metal dielectric (IMD).

The logic die base 192 may be disposed below the front side structure 191. The logic die base 192 may include the activation surface and a back side which is an opposite side to the activation surface. The logic die base 192 may be a die formed from the wafer. In an embodiment, the logic die base 192 may include silicon or another semiconductor material. The logic die base 192 may include through silicon vias 195 and buried power rails (BPR) 194.

The through silicon vias 195 may be disposed in the logic die base 192. Each of through silicon vias 195 may be disposed between each of upper connection pads 196 of the BSPDN 193, and each of buried power rails (BPR) 194. Each of through silicon vias 195 may electrically connect each of buried power rails (BPR) 194 to each of upper connection pads 196 of the BSPDN 193. In an embodiment, the through silicon vias 195 may include at least one of the tungsten, the aluminum, the copper, and an alloy thereof.

Each of buried power rails (BPR) 194 may be disposed between each of through silicon vias 195 and the activation layer of the front side structure 191. The buried power rails (BPR) 194 serve to transfer power to the integrated circuit structure of the activation layer. In an embodiment, the buried power rails (BPR) 194 may include at least one of cobalt, tungsten, ruthenium, and an alloy thereof.

The BSPDN 193 may be disposed on the back side of the logic die base 192. The BSPDN 193 may include the upper connection pads 196, the wiring contact plugs 197, power supply lines 198, lower connection pads 199, and the inter metal dielectric (IMD). The upper connection pads 196, the wiring contact plugs 197, the power supply lines 198, and the lower connection pads 199 may be disposed sequentially from the top, and may form a vertical power routing path in which power transferred via the first capacitor die 130A and the lower interconnection structure 150 is transferred to the integrated circuit structure of the activation layer. In an embodiment, the inter metal dielectric (IMD) may include SiO_{2,} SiOC, SiOH, SiOCH, or a low-k dielectric layer. In an embodiment, each of the upper connection pads 196, the wiring contact plugs 197, the power supply lines 198, and the lower connection pads 199 may include at least one of copper, aluminum, tungsten, nickel, gold, tin, titanium, and the alloy thereof.

The second capacitor die 130B may be disposed on the redistribution structure 120. The second capacitor die 130B may be in contact with the redistribution structure 120. The second capacitor die 130B may be disposed below the high bandwidth memory 180. The second capacitor die 130B may be disposed next to the 3D integrated circuit structure SB. There may be a plurality of second capacitor dies 130B. The plurality of second capacitor dies 130B may be disposed around the 3D integrated circuit structure SB. A level of an upper surface of the second capacitor die 130B may be the same as a level of an upper surface of the 3D integrated circuit structure SB. In an embodiment, the second capacitor die 130B may serve as a decoupling capacitor. The second capacitor die 130B may protect the high bandwidth memory 180 from noise in a process in which power is transferred to the high bandwidth memory 180.

The second capacitor die 130B may include the same configuration as the first capacitor die 130A of FIG. 1. A vertical height of the capacitor die base 141 of the second capacitor die 130B may be equal to a sum of a height of the lower interconnection structure 150 of the 3D integrated circuit structure SB and a height of the logic die 190.

The upper interconnection structures 170 may include a first interconnection structure 170A, a second interconnection structure 170B. There may be a plurality of first interconnection structures 170A or second interconnection structures 170B. The first interconnection structure 170A may be disposed between the second capacitor die 130B and the high bandwidth memory (HBM) 180. Connection members 176 of the first interconnection structure 170A may electrically connect the high bandwidth memory (HBM) 180 to the second capacitor die 130B. The second interconnection structures 170B may be disposed between the 3D integrated circuit structure SB and the high bandwidth memory (HBM) 180. Connection members 176 of the second interconnection structure 170B may electrically connect the high bandwidth memory (HBM) 180 to the 3D integrated circuit structure SB.

Each of upper interconnection structures 170 may include the connection members 176 and insulation members 178 around the connection members 176. In an embodiment, the connection members 176 may include micro bumps. The insulation member 178 may surround, protect, and insulate the bonding pads 175 of the second capacitor die 130B, the bonding pads 175 of the 3D integrated circuit structure SB, the connection members 176, and the connection pads 177 of the high bandwidth memory 180. In an embodiment, the insulation member 178 may include a non-conductive film (NCF).

According to the present disclosure, the activation surface of the buffer die 160 of the high bandwidth memory (HBM) 180, and the activation surface of the logic die 190 may be directly connected without the bridge die by the second interconnection structure 170B. As a result, the signal transfer distance between the high bandwidth memory (HBM) 180 and the logic die 190 may be reduced, and a signal transfer speed may be enhanced.

The high bandwidth memory (HBM) 180 may be disposed on the 3D integrated circuit structure SB, and on the second capacitor die 130B. The high bandwidth memory (HBM) 180 may be disposed side by side with the dummy die D. There may be a plurality of high bandwidth memories (HBM) 180. The plurality of high bandwidth memories (HBM) 180 may be disposed around the dummy die D. The high bandwidth memory (HBM) 180 may include the buffer die 160, and the memory stack S on the buffer die 160. The buffer die 160 may include a buffer die base including the activation surface and a back side which is an opposite side to the activation surface, and an FSPDN on the activation surface. The buffer die 160 may be disposed so that the FSPDN faces the second capacitor die 130B and the 3D integrated circuit structure SB. The memory stack S may include memory dies (core dies) 181 and interconnection structures 182. The memory dies 181 may be stacked in the vertical direction, and sequentially. In an embodiment, the memory dies 181 may include DRAMs. Each of interconnection structures 182 may be disposed between the buffer die 160 and the memory stack S, or between neighboring memory dies 181 among the memory dies 181. Each of interconnection structures 182 may include connection members and insulation members around the connection members. In an embodiment, the connection members may include micro bumps. In an embodiment, the insulation member may include the non-conductive film (NCF).

A bonding member F may be disposed between the 3D integrated circuit structure SB and the dummy die D. The bonding member F may attach the dummy die D to the 3D integrated circuit structure SB. In an embodiment, the bonding member F may include a thermal interface material (TIM). The thermal interface material (TIM) is inserted between the 3D integrated circuit structure SB generating heat and the dummy die D discharging heat to enhance heat binding of the 3D integrated circuit structure SB and the dummy die D. The thermal interface material (TIM) serves to reduce thermal contact resistance by filling an air layer of a contact surface between the 3D integrated circuit structure SB and the dummy die D. In an embodiment, the bonding member F may include a die attach film (DAF).

The dummy die D may be disposed on the 3D integrated circuit structure SB. The dummy die D may be electrically separated from another component. For example, the dummy die D may be electrically isolated and not electrically connected to any components. The dummy die D may be a heat dissipation structure. The dummy die D may be thermally connected to the 3D integrated circuit structure SB. The dummy die D may be surrounded by the molding material 101. The upper surface of the dummy die D may be exposed form the molding material 101. The upper surface of the dummy die D may be coplanar with the upper surface of the molding material 101. In an embodiment, the dummy die D may include a conductive material having high thermal conductivity, such as copper or aluminum. In an embodiment, the dummy die D may include a heat slug, a heat sink, or a heat spreader. In an embodiment, the dummy die D may include copper, aluminum, gold, silver, iron, or stainless steel (SUS). In an embodiment, the dummy die D may be made of a silicon material having higher thermal conductivity than the molding material 101. The dummy die D serves to discharge heat generated from the 3D integrated circuit structure SB or the semiconductor package 100BA.

The molding material 101 may cover the 3D integrated circuit structure SB, the second capacitor die 130B, the upper interconnection structure 170, the high bandwidth memory 180, the bonding member F, and the dummy die D on the redistribution structure 120. The molding material 101 may protect the 3D integrated circuit structure SB, the second capacitor die 130B, the upper interconnection structure 170, the high bandwidth memory 180, the bonding member F, and the dummy die D from an external environment. The upper surface of the memory stack S and the upper surface of the dummy die D may be exposed to the outside from the molding material 101. The upper surface of the memory stack S and the upper surface of the dummy die D may be coplanar with the upper surface of the molding material 101.

The components described regarding FIG. 1 may be applied to components other than the components described regarding FIG. 5.

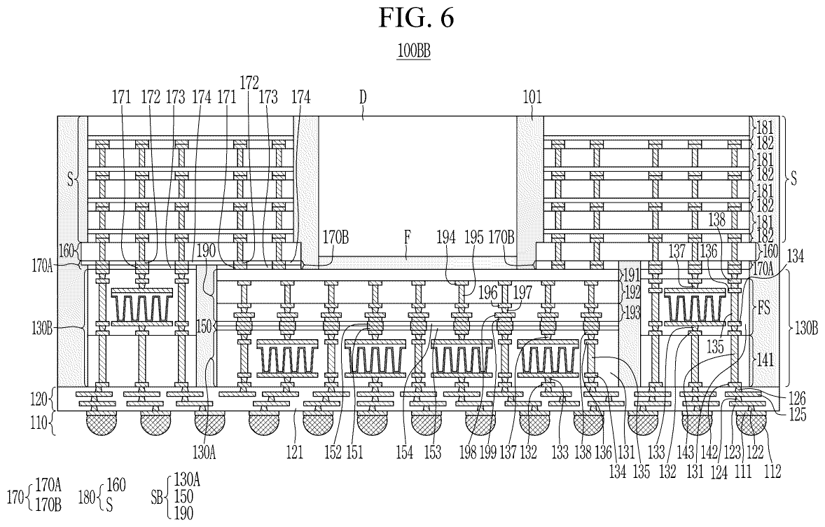

FIG. 6 is a cross-sectional view illustrating a semiconductor package 100BB according to an embodiment.

Referring to FIG. 6, the semiconductor package 100BB may be formed in a scheme in which the 3D integrated circuit structure SB and the second capacitor die 130B at a lower portion, and the high bandwidth memory (HBM) 180 at an upper portion are bonded by hybrid bonding.

The upper interconnection structures 170 may include a first interconnection structure 170A and a second interconnection structure 170B. There may be a plurality of first interconnection structures 170A or second interconnection structures 170B. The first interconnection structure 170A may be disposed between the second capacitor die 130B and the high bandwidth memory (HBM) 180. The first interconnection structure 170A may electrically connect the high bandwidth memory (HBM) 180 to the second capacitor die 130B. The second interconnection structures 170B may be disposed between the 3D integrated circuit structure SB and the high bandwidth memory (HBM) 180. The second interconnection structure 170B may electrically connect the high bandwidth memory (HBM) 180 to the 3D integrated circuit structure SB. The upper interconnection structures 170 may include first conductive pads 171, second conductive pads 172, a first silicon insulation layer 173, and a second silicon insulation layer 174.

The components described regarding FIG. 3 may be applied to components other than the components described regarding FIG. 6.

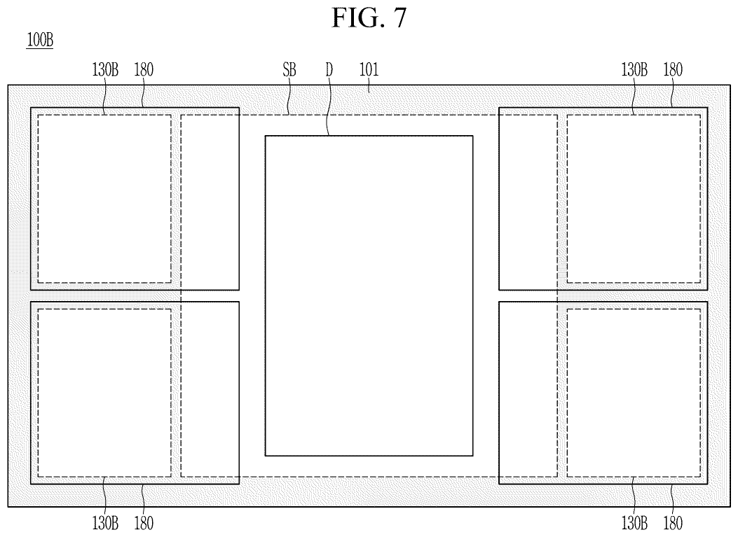

FIG. 7 is a plan view illustrating an upper surface of the semiconductor package 100BA of FIG. 5 and an upper surface of the semiconductor package 100BB of FIG. 6. The dummy die D and the high bandwidth memories (HBM) 180 are illustrated in solid lines, and the 3D integrated circuit structure SB and the second capacitor dies 130B are illustrated in dotted lines.

Referring to FIG. 7, the high bandwidth memories (HBM) 180 may be disposed around the dummy die D. Each of second capacitor dies 130B may be disposed below each of high bandwidth memories (HBM) 180. The 3D integrated circuit structure SB may be disposed below the high bandwidth memory (HBM) 180, and below the dummy die D.

A footprint of the dummy die D may be included in a footprint of the 3D integrated circuit structure SB. Footprints of each of second capacitor dies 130B may be included in footprints of each of high bandwidth memories (HBM) 180. The footprints of each of high bandwidth memories (HBM) 180 may overlap with the footprint of the 3D integrated circuit structure SB, and the footprints of each of second capacitor dies 130B.

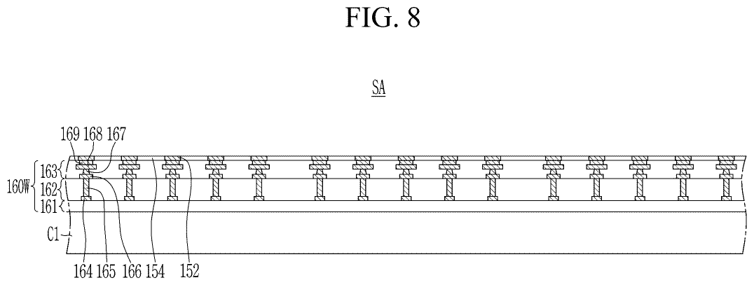

FIGS. 8 to 11 are cross-sectional views illustrated to describe a method for manufacturing a 3D integrated circuit structure SA of FIG. 1. The method for manufacturing the 3D integrated circuit structure SA of FIG. 1 may be applied to a method for manufacturing the 3D integrated circuit structure SB of FIG. 5.

FIG. 8 is a cross-sectional view illustrating a step of forming the BSPDN 163 on the back side of the buffer die base 162 in which the front side structure 161 is formed.

Referring to FIG. 8, a first carrier C1 is provided. In an embodiment, the first carrier C1 may include a silicon based material such as glass or a silicon oxide, other materials such as an organic material or an aluminum oxide, or any combination of the materials, etc. Thereafter, the front side structure 161 may bond a first wafer 160W including buffer die bases 162 including the through silicon vias 165 and the front side structures 161 on the buffer die bases 162 to the first carrier C1 to face the first carrier C1.

The first wafer 160W may be bonded to the first carrier C1, and then the inter metal dielectric (IMD) of the BSPDN 163, and the upper connection pads 166, the wiring contact plugs 167, the power supply lines 168, and the lower connection pads 169 in the inter metal dielectric (IMD) may be formed. In an embodiment, the inter metal dielectric (IMD) may be formed by chemical vapor deposition (CVD). In an embodiment, the upper connection pads 166, the wiring contact plugs 167, the power supply lines 168, and the lower connection pads 169 may be formed by forming openings and contact holes by performing the photolithography process, and filling the openings or the contact holes with conductive materials by electrolytic plating.

Thereafter, the second conductive pads 152 and the second silicon insulation layer 154 may be formed on the BSPDN 163 of the first wafer 160W.

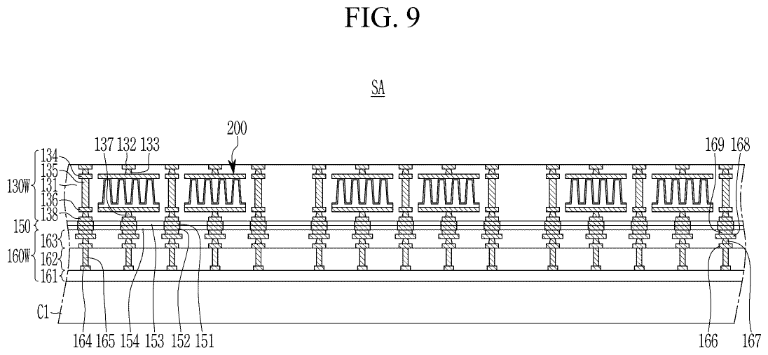

FIG. 9 is a cross-sectional view illustrating a step of bonding the first wafer 160W and the second wafer 130W by hybrid bonding.

Referring to FIG. 9, the second wafer 130W including capacitor structures 200, in which the first conductive pads 151 and the first silicon insulation layer 153 are formed may be bonded onto the first wafer 160W by hybrid bonding.

A chemical mechanical planarization (CMP) process may be performed before the hybrid bonding. In an embodiment, surface roughness of each of bonding surfaces which are subjected to the hybrid bonding may be approximately 10 Å or less. Then, a bonding surface of the second silicon insulation layer 154 formed in the first wafer 160W and a bonding surface of the first silicon insulation layer 153 formed in the second wafer 130W may be activated. In an embodiment, the bonding surface of the first silicon insulation layer 153 and the bonding surface of the second silicon insulation layer 154 may be subjected to be surface treatment by plasma activation. Then, the first wafer 160W and the second wafer 130W may be aligned for the hybrid bonding. Then, the activated bonding surface of the second silicon insulation layer 154 formed in the first wafer 160W and the activated bonding surface of the first silicon insulation layer 153 formed in the second wafer 130W may be in contact with each other, and may be pre-bonded.

Thereafter, the first wafer 160W and the second wafer 130W may be hybrid-bonded. First, the second silicon insulation layer 154 formed in the first wafer 160W and the first silicon insulation layer 153 formed in the second wafer 130W may be bonded by treatment. Bonding of the second silicon insulation layer 154 formed in the pre-bonded first wafer 160W and the first silicon insulation layer 153 formed in the second wafer 130W may be strengthened by the treatment.

Then, each of the second conductive pads 152 formed in the first wafer 160W and each of the first conductive pads 151 formed in the second wafer 130W may be bonded by annealing.

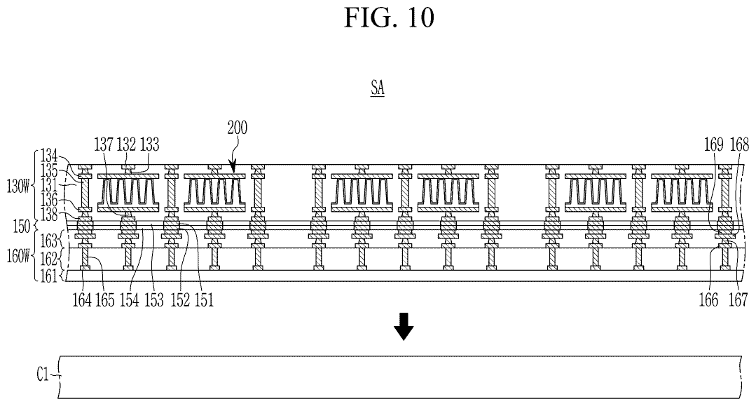

FIG. 10 is a cross-sectional view illustrating a step of removing the first carrier C1.

Referring to FIG. 10, the first carrier C1 may be removed from a front side of the first wafer 160W.

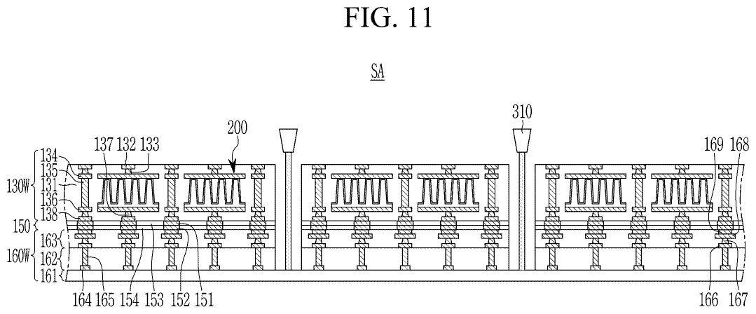

FIG. 11 is a cross-sectional view illustrating a step of individualizing the bonded first wafer 160W and second wafer 130W.

Referring to FIG. 11, the 3D integrated circuit structures SA may be formed by individualizing the bonded first wafer 160W and second wafer 130W by using an individualization equipment 310. In an embodiment, as the individualization equipment 310, a blade, laser, or plasma equipment may be used.

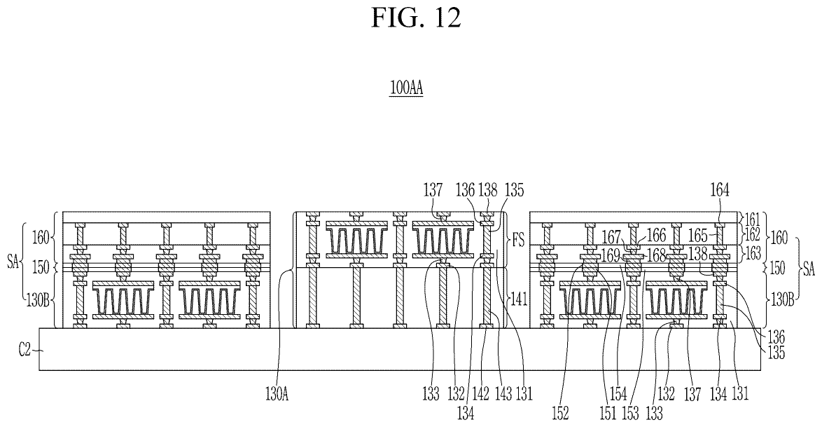

FIGS. 12 to 22 are cross-sectional views illustrated to describe a method for manufacturing the semiconductor package 100AA according to an embodiment of FIG. 1. The method for manufacturing the semiconductor package 100AA according to an embodiment of FIG. 1 may be applied to the methods for manufacturing the semiconductor package 100AB according to an embodiment of FIG. 2, the semiconductor package 100BA according to an embodiment of FIG. 5, and the semiconductor package 100BB according to an embodiment of FIG. 6.

FIG. 12 is a cross-sectional view illustrating a step of bonding the first capacitor dies 130A and the 3D integrated circuit structure SA on a second carrier C2.

Referring to FIG. 12, the second carrier C2 is provided. In an embodiment, the second carrier C2 may include a silicon based material such as glass or a silicon oxide, other materials such as an organic material or an aluminum oxide, or any combination of the materials, etc. Thereafter, the first capacitor die 130A and the 3D integrated circuit structure SA may be bonded onto the second carrier C2.

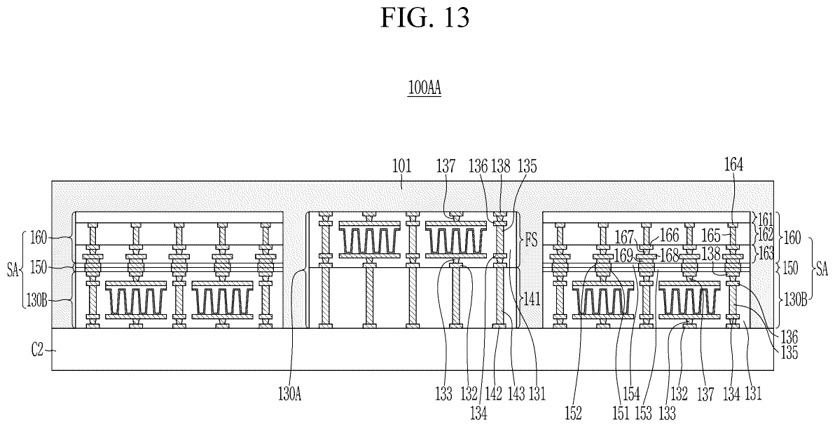

FIG. 13 is a cross-sectional view illustrating a step of molding the first capacitor dies 130A and the 3D integrated circuit structure SA on the redistribution structure 120.

Referring to FIG. 13, the first capacitor dies 130A and the 3D integrated circuit structure SA may be molded with the molding material 101 on the redistribution structure 120. As an embodiment, a process of molding the first capacitor dies 130A and the 3D integrated circuit structure SA with the molding material 101 may include a compression molding or transfer molding process. In an embodiment, the molding material 101 may include an epoxy molding compound (EMC).

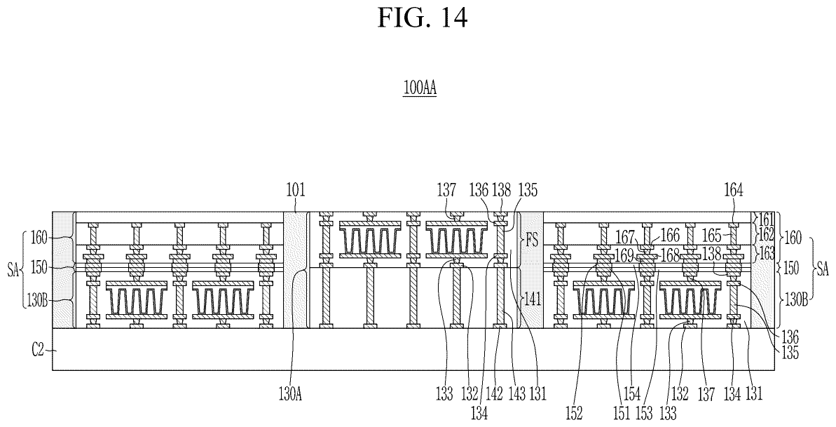

FIG. 14 is a cross-sectional view illustrating a step of performing a chemical mechanical planarization (CMP) process in the molding material 101.

Referring to FIG. 14, the chemical mechanical planarization (CMP) process is performed to planarize an upper surface of the molding material 101. After performing the chemical mechanical planarization (CMP) process, the upper surfaces of the first capacitor dies 130A, and the upper surface of the 3D integrated circuit structure SA may be exposed. For example, the upper surfaces of the first capacitor dies 130A may be coplanar with the upper surface of the 3D integrated circuit structure SA.

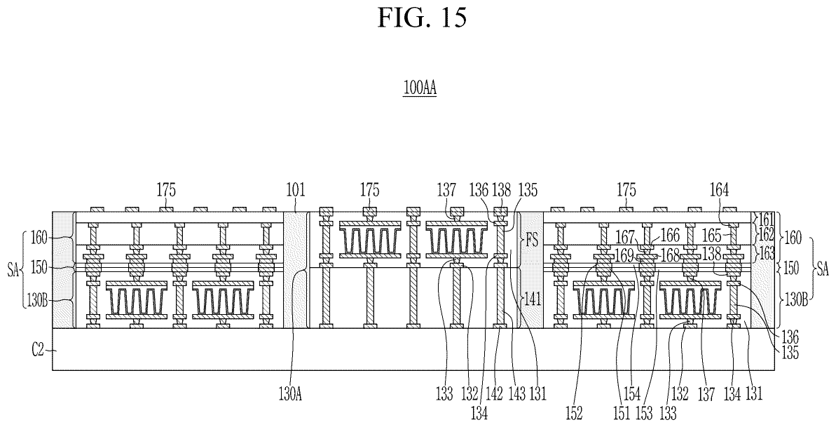

FIG. 15 is a cross-sectional view illustrating a step of forming the bonding pads 175 on the upper surfaces of the first capacitor dies 130A, and on the upper surface of the 3D integrated circuit structure SA.

Referring to FIG. 15, the bonding pads 175 may be formed on the upper surfaces of the first capacitor dies 130A, and on the upper surface of the 3D integrated circuit structure SA. In an embodiment, the bonding pads 175 may be formed by forming the openings by the photolithography process, and filling the openings with the conductive material by the electrolytic plating.

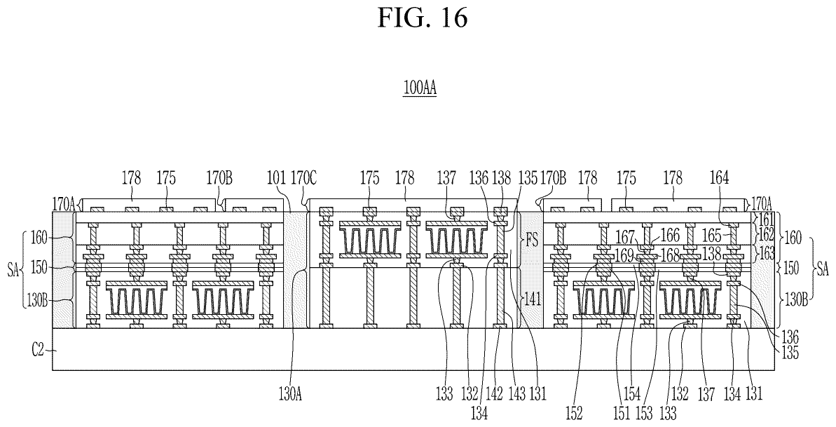

FIG. 16 is a cross-sectional view illustrating a step of attaching the insulation members 178 on the upper surfaces of the first capacitor dies 130A, and on the upper surface of the 3D integrated circuit structure SA.

Referring to FIG. 16, the insulation members 178 may be attached onto the upper surfaces of the first capacitor dies 130A, and on the upper surface of the 3D integrated circuit structure SA.

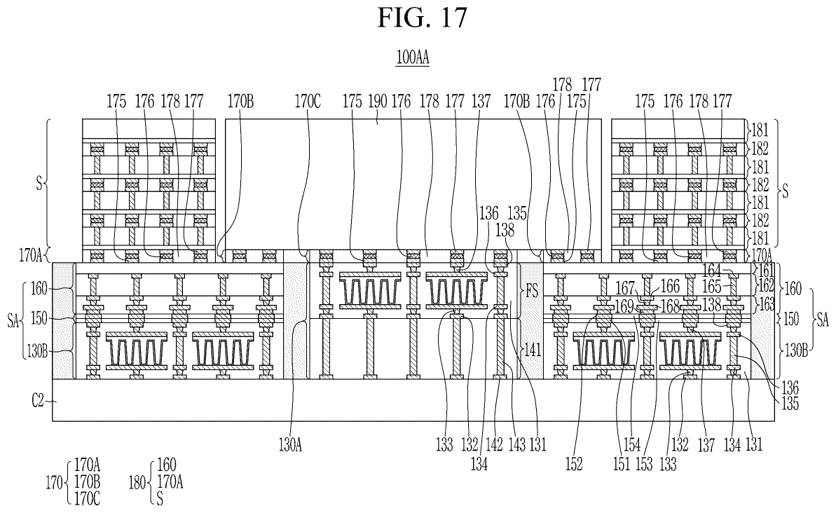

FIG. 17 is a cross-sectional view illustrating a step of mounting the memory stacks S and the logic die 190.

Referring to FIG. 17, the logic die 190 may be mounted on the first capacitor dies 130A, and on the 3D integrated circuit structure SA. Each of memory stacks S may be mounted on each of 3D integrated circuit structures SA. The connection members 176 connected to the connection pads 177 of the logic die 190 may be connected to the bonding pads 175 of each of 3D integrated circuit structures SA or each of first capacitor dies by penetrating the insulation member 178. The connection members 176 connected to the connection pads 177 of each of memory stacks S may be connected to the bonding pads 175 of each of 3D integrated circuit structures SA by penetrating the insulation member 178. The memory stacks S and the logic die 190 may be mounted based on a chip-on-wafer (CoW) process technology. In an embodiment, the memory stack S may be mounted on the 3D integrated circuit structure SA by performing a flip chip bonding process. In an embodiment, the logic die 190 may be mounted on the first capacitor dies 130A, and on the 3D integrated circuit structure SA by performing the flip chip bonding process.

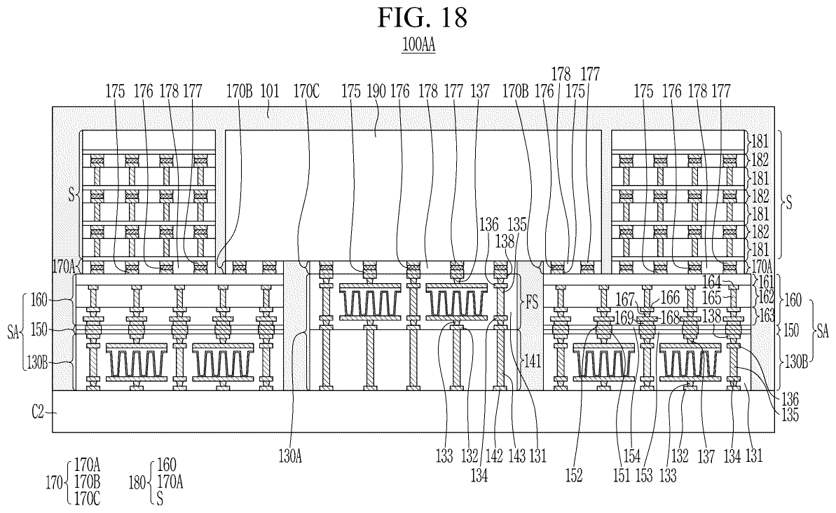

FIG. 18 is a cross-sectional view illustrating a step of molding the memory stacks S and the logic die 190 on the molding material 101, the first capacitor dies 130A, and the 3D integrated circuit structures SA.

Referring to FIG. 18, the memory stacks S and the logic die 190 may be molded with the molding material 101 on the molding material 101, the first capacitor dies 130A, and the 3D integrated circuit structures SA. As an embodiment, the process of molding the memory stacks S and the logic die 190 with the molding material 101 may include a compression molding or transfer molding process. In an embodiment, the molding material 101 may include an epoxy molding compound (EMC).

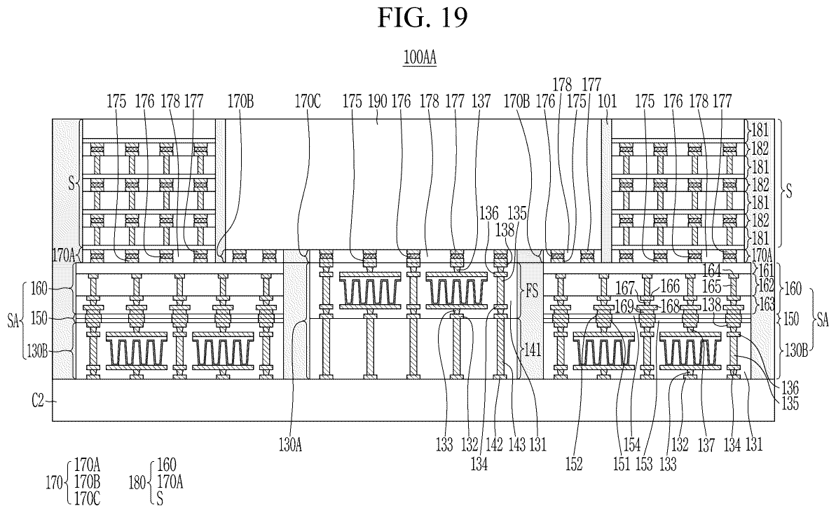

FIG. 19 is a cross-sectional view illustrating a step of performing the chemical mechanical planarization (CMP) process in the molding material 101.

Referring to FIG. 19, the chemical mechanical planarization (CMP) process is performed to planarize the upper surface of the molding material 101. After performing the chemical mechanical planarization (CMP) process, the upper surfaces of the memory stacks S, and the upper surface of the logic die 190 may be exposed. For example, the upper surfaces of the memory stacks S may be coplanar with the upper surface of the logic die 190.

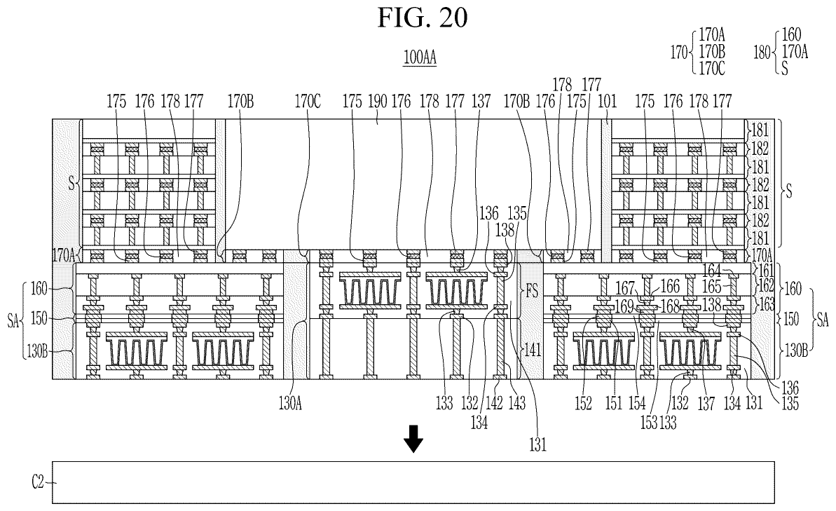

FIG. 20 is a cross-sectional view illustrating a step of removing the second carrier C2.

Referring to FIG. 20, the second carrier C2 may be removed from a lower surface of the molding material 101, lower surfaces of the first capacitor dies 130A, and lower surfaces of the 3D integrated circuit structures SA.

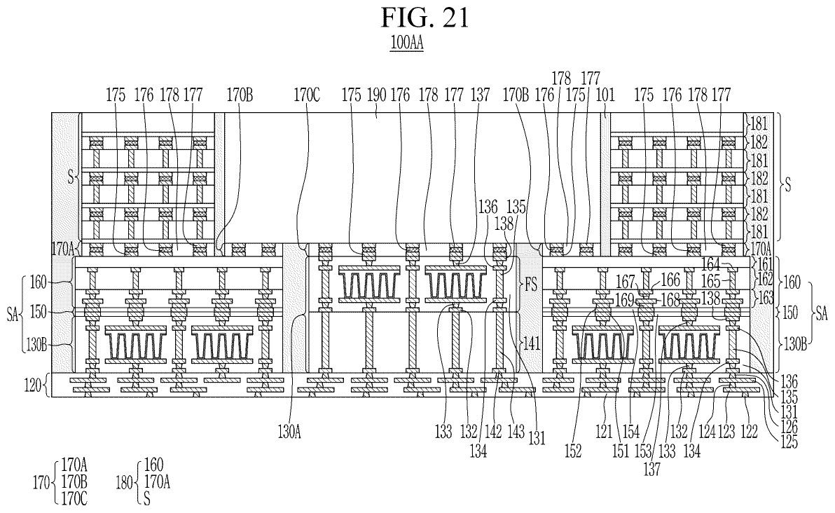

FIG. 21 is a cross-sectional view illustrating a step of forming the redistribution structure 120 on the lower surface of the molding material 101, the lower surfaces of the first capacitor dies 130A, and the lower surfaces of the 3D integrated circuit structures SA.

Referring to FIG. 21, the redistribution structure 120 may be formed on the lower surface of the molding material 101, the lower surfaces of the first capacitor dies 130A, and the lower surfaces of the 3D integrated circuit structures SA. The third redistribution vias 126, the second redistribution lines 125, the second redistribution vias 124, the first redistribution lines 123, and the first redistribution vias 122 in the dielectric 121 may be sequentially formed. By such a manufacturing order, each of the first redistribution vias 122, the second redistribution vias 124, and the third redistribution vias 126 may have a shape in which a width decreases from the bottom to the top.

In an embodiment, the dielectric 121 may include a photoimageable dielectric (PID) used in a redistribution process. The PID is a material which may form a fine pattern by applying the photolithography process. As an embodiment, the PID may include a polyimide-based photoimageable polymer, a Novorak-based photoimageable polymer, polybenzoxazole, a silicone-based polymer, an acrylate-based polymer, or an epoxy-based polymer. In an embodiment, the dielectric 121 may be formed by performing a spin coating process. The first redistribution vias 122, the first redistribution lines 123, the second redistribution vias 124, the second redistribution lines 125, and the third redistribution vias 126 may be formed by forming the openings or the via holes by performing the photolithography process, and filling the openings or via holes with the conductive material by the electrolytic plating.

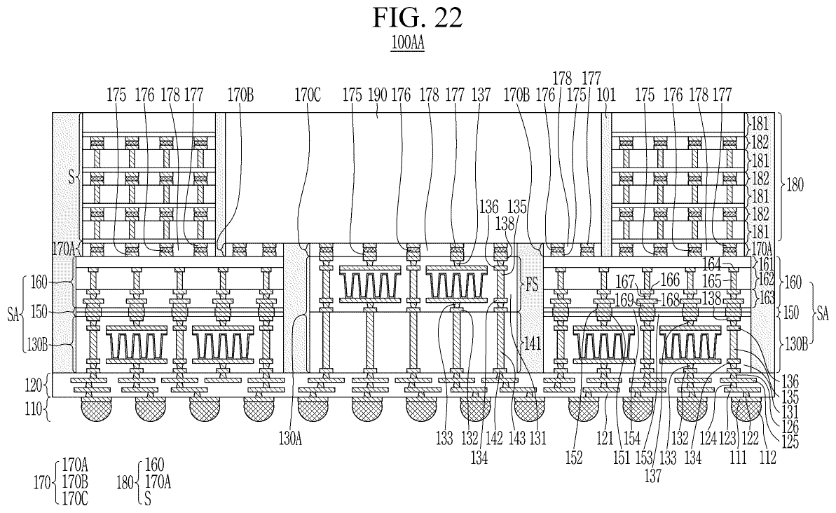

FIG. 22 is a cross-sectional view illustrating a step of forming the connection structure 110 on the lower surface of the redistribution structure 120.

Referring to FIG. 22, the connection structure 110 may be formed on the lower surface of the redistribution structure 120. The connection pads 111 are formed below the first redistribution vias 122 of the redistribution structure 120. In an embodiment, the connection pads 111 may include at least one of copper, nickel, zinc, gold, silver, platinum, palladium, chrome, titanium, and an alloy thereof. In an embodiment, the connection pads 111 may be formed by form the openings by performing the photolithography process, and performing a sputtering process, or forming a seed metal layer, and then performing the electrolytic plating process. Thereafter, the external connection member 112 is formed below the connection pads 111. In an embodiment, the external connection member 112 may include at least one of tin, silver, lead, nickel, copper, and an alloy thereof.

Although a preferred embodiment of the present disclosure is described hereinabove, the present disclosure is not limited thereto, and various modifications can be made within the scopes of the claims, and the detailed description of the present disclosure and the accompanying drawings, and belongs to the scope of the present disclosure, of course.

What is claimed is:

1. A semiconductor package comprising:
a redistribution structure;
a first capacitor die on the redistribution structure;
a 3D integrated circuit structure on the redistribution structure, and next to the first capacitor die;
a logic die on the first capacitor die, and on the 3D integrated circuit structure; and
a memory stack on the 3D integrated circuit structure,
wherein the 3D integrated circuit structure includes,
a second capacitor die; and
a buffer die on the second capacitor die.

2. The semiconductor package of claim 1, wherein:
the buffer die includes,
a buffer die base including an activation surface and a back side which is an opposite side to the activation surface, and
a back side power delivery network (BSPDN) on the back side.

3. The semiconductor package of claim 2, wherein:
the buffer die is disposed so that the BSPDN faces the second capacitor die.

4. The semiconductor package of claim 1, wherein:
the logic die includes,
a logic die base including an activation surface and a back side which is an opposite side to the activation surface, and
a front side power delivery network (FSPDN) on the activation surface.

5. The semiconductor package of claim 4, wherein:
the logic die is disposed so that the FSPDN faces the first capacitor die, and the 3D integrated circuit structure.

6. The semiconductor package of claim 1, wherein:
the logic die is disposed so that an activation surface of the logic die faces the first capacitor die, and the 3D integrated circuit structure, and
the buffer die is disposed so that an activation surface of the buffer die faces the logic die, and the memory stack.

7. The semiconductor package of claim 1, wherein:
each of the first capacitor die and the second capacitor die includes an integrated stack capacitor (ISC) die.

8. The semiconductor package of claim 1, wherein:
the first capacitor die includes,
a capacitor die base,
a capacitor structure on the capacitor die base, and
a plurality of through silicon vias in the capacitor die base.

9. A semiconductor package comprising:
a redistribution structure;
a 3D integrated circuit structure on the redistribution structure, wherein the 3D integrated circuit structure includes
a first capacitor die, and
a logic die on the first capacitor die;
a second capacitor die on the redistribution structure, and next to the 3D integrated circuit structure;
a buffer die on the 3D integrated circuit structure, and on the second capacitor die; and
a memory stack on the buffer die.

10. The semiconductor package of claim 9, wherein:
the logic die includes,
a logic die base including an activation surface and a back side which is an opposite side to the activation surface, and
a back side power delivery network (BSPDN) on the back side.

11. The semiconductor package of claim 10, wherein:
the logic die is disposed so that the BSPDN faces the first capacitor die.

12. The semiconductor package of claim 9, wherein:
the buffer die includes
a buffer die base including an activation surface and a back side which is an opposite side to the activation surface, and
a front side power delivery network (FSPDN) on the activation surface.

13. The semiconductor package of claim 12, wherein:
the buffer die is disposed so that the FSPDN faces the second capacitor die, and the 3D integrated circuit structure.

14. The semiconductor package of claim 9, wherein:
the second capacitor die includes,
a capacitor die base,
a capacitor structure on the capacitor die base, and
a plurality of through silicon vias in the capacitor die base.

15. The semiconductor package of claim 9, further comprising:
a dummy die on the 3D integrated circuit structure.

16. A semiconductor package comprising:
a redistribution structure;
one or more first capacitor dies on the redistribution structure;
a plurality of 3D integrated circuit structures on the redistribution structure, and around the one or more first capacitor dies;
a logic die on the one or more first capacitor dies, and on the plurality of 3D integrated circuit structures;
a plurality of memory stacks around the logic die, wherein each of the plurality of memory stacks is disposed on a corresponding 3D integrated circuit structure among the plurality of 3D integrated circuit structures; and
a molding material covering the one or more first capacitor dies, the plurality of 3D integrated circuit structures, the logic die, and the plurality of memory stacks on the redistribution structure,
wherein each of the plurality of 3D integrated circuit structures includes
a second capacitor die, and
a buffer die on the second capacitor die.

17. The semiconductor package of claim 16, further comprising:
a plurality of first interconnection structures between the plurality of 3D integrated circuit structures and the plurality of memory stacks, wherein each first interconnection structure among the plurality of first interconnection structures electrically connects each memory stack of the plurality of memory stacks to each 3D integrated circuit structure of the plurality of 3D integrated circuit structures;
a plurality of second interconnection structures between the plurality of 3D integrated circuit structures and the logic die, wherein each second interconnection structure among the plurality of second interconnection structures electrically connects the logic die to each 3D integrated circuit structure of the plurality of 3D integrated circuit structures; and
one or more third interconnection structures between the one or more first capacitor dies and the logic die.

18. The semiconductor package of claim 17, wherein:
the plurality of first interconnection structures, the plurality of second interconnection structures, and the one or more third interconnection structures include
a plurality of micro bumps, and
an insulation member around the plurality of micro bumps.

19. The semiconductor package of claim 17, wherein:
the plurality of first interconnection structures, the plurality of second interconnection structures, and the one or more third interconnection structures include
a plurality of first conductive pads,
a first silicon insulation layer surrounding the plurality of first conductive pads,
a plurality of second conductive pads located on the plurality of first conductive pads, and each second conductive pad of the plurality of second conductive pads directly bonded to each of first conductive pad of the plurality of first conductive pads, and
a second silicon insulation layer surrounding the plurality of second conductive pads, located on the first silicon insulation layer, and directly bonded to the first silicon insulation layer.

20. The semiconductor package of claim 16, wherein:
the one or more first capacitor dies and the plurality of 3D integrated circuit structures are in contact with the redistribution structure.
